(19) United States
(12) Patent Application Publication
(10) Pub. No.: US 2024/0136303 A1
(43) Pub. Date: Apr. 25, 2024

(54) WAFER ALIGNMENT STRUCTURE

(71) Applicant: Tesla, Inc., Austin, TX (US)

(72) Inventors: Yong guo Li, Gilroy, CA (US); Rishabh Bhandari, San Carlos, CA (US); Aydin Nabovati, Toronto (CA); Ron Rosenberg, San Francisco, CA (US); Vijaykumar Krithivasan, Mountain View, CA (US); Mitchell Heschke, Los Altos, CA (US)

(21) Appl. No.: 18/548,433

(22) PCT Filed: Feb. 23, 2022
(86) PCT No.: PCT/US2022/017504

§ 371 Date: Aug. 29, 2023

Related U.S. Application Data
(60) Provisional application No. 63/155,202, filed on Mar. 1, 2021.

(51) Int. Cl. H01L 23/544; H01L 23/367

(52) U.S. Cl. CPC H01L 23/544; H01L 23/367; H01L 2223/54426

(57) ABSTRACT

A system on a wafer (SoW) assembly is disclosed. The SoW assembly can include a first SoW assembly structure with a first coefficient of thermal expansion (CTE). The first SoW assembly structure includes first to third slots at different locations. The SoW assembly can include a second SoW assembly structure stacked on the first SoW assembly structure. The second SoW assembly structure has a second CTE different from the first CTE. The second SoW assembly structure has first to third pins extending therefrom and disposed in the first to third slots. The first and second slots shaped to allow the first and second pins to move along a first axis, and the third slot shaped to allow the third pin to move along a second axis. The first SoW assembly structure can be a SoW and the second SoW assembly structure can be a heat dissipation structure in certain applications.

### CROSS-REFERENCE TO RELATED APPLICATION

This application claims the benefit of U.S. Provisional Patent Application No. 63/155,202, titled “WAFER ALIGNMENT STRUCTURE,” filed Mar. 1, 2021, the disclosure of which is incorporated herein by reference in its entirety and for all purposes.

### TECHNICAL FIELD

The present disclosure relates generally to alignment structures, and more specifically to wafer level alignment structure.

### BACKGROUND

Precise alignment of an element to another element at wafer level can be challenging. In a system, such as a system on a wafer assembly, a high coefficient of thermal expansion (CTE) element and a low CTE element can be mounted to one another. For example, a system on a wafer and a heat dissipation structure can have different CTEs and be attached to each other. A mismatch between the CTEs of the elements cause misalignment between the elements due to thermal stress.

### SUMMARY OF CERTAIN INVENTIVE ASPECTS

In one aspect, a system on a wafer (SoW) assembly is disclosed. The SoW assembly can include a first SoW assembly structure that includes a first slot at a first location, a second slot at a second location, and a third slot at a third location. The SoW assembly can include a second SoW assembly structure that is stacked with the first SoW assembly structure. The second SoW assembly structure has a first pin that extends therefrom and at least partially disposed in the first slot, a second pin that extends therefrom and at least partially disposed in the second slot, and a third pin that extends therefrom and at least partially disposed in the third slot. The first slot and the second slot are shaped so as to allow the first pin and the second pin to move along a first axis in a plane, and the third slot is shaped so as to allow the third pin to move along a second axis in the plane that is different from the first axis. Either the first SoW assembly structure or the second SoW assembly structure is included in a thermal system that is configured to cool a SoW.

In one embodiment, the element can be stacked with the SoW.

In one embodiment, the element includes the SoW. The SoW assembly can further include a reinforcement feature coupled to the SoW. The reinforcement feature can include an opening that aligns with the first slot. A size of the opening can be smaller than a size of the first slot such that the reinforcement feature impedes the first pin from physically contacting the SoW. The opening can have an oval shape. The first axis can be substantially perpendicular to the second axis.

In one aspect, a system on a wafer (SoW) assembly is disclosed. The SoW assembly can include a first SoW assembly structure that has a first coefficient of thermal expansion, the first SoW assembly structure including a first slot at a first location, a second slot at a second location, and a third slot at a third location. The SoW assembly can include a second SoW assembly structure that is stacked on the first SoW assembly structure, and configured to dissipate heat from a SoW. The second SoW assembly structure has a second coefficient of thermal expansion that is different from the first coefficient of thermal expansion. The second SoW assembly structure has a first pin that extends therefrom and at least partially disposed in the first slot, a second pin that extends therefrom and at least partially disposed in the second slot, and a third pin that extends therefrom and at least partially disposed in the third slot. The first slot and the second slot are shaped so as to allow the first pin and the second pin to move along a first axis in a plane, and the third slot is shaped so as to allow the third pin to move along a second axis in the plane, the second axis being different from the first axis.

In one embodiment, the first SoW assembly structure is stacked with a SoW.

In one embodiment, the second coefficient of thermal expansion is greater than the first coefficient of thermal expansion.

In one embodiment, the first SoW assembly structure comprises a SoW. The SoW assembly can further include a reinforcement feature that is coupled with the SoW. The reinforcement feature can include an opening that aligns with the first slot, and a size of the opening can be smaller than a size of the first slot.

In one embodiment, the first axis and the second axis are substantially perpendicular to each other.

In one embodiment, the first slot comprises an oval slot configured to receive the first pin, and wherein a major axis of the oval slot of the first slot extends along the first axis. The third slot can include an oval slot that is configured to receive the third pin, and a major axis of the oval slot of the third slot can extend along the second axis.

In one embodiment, the second SoW assembly structure includes a heat dissipation structure.

In one embodiment, the first SoW assembly structure can include no more than three slots that are configured to receive pins that extend from the second SoW assembly structure.

In one aspect, a wafer with an alignment structure for aligning the wafer with an element that is stacked vertically on the wafer is disclosed. The wafer can include a first slot that is formed at a first location of the wafer. The first slot is configured to mate with a first pin and to align the wafer and the element along a first axis. The first slot is shaped to allow the wafer to move along the first axis when the first slot and the first pin are mated. The wafer can include a second slot that is formed at a second location of the wafer different from the first location. The second slot is configured to mate with a second pin and to align the wafer and the element along the first axis. The wafer can include a third slot that is formed at a third location of the wafer different from the first and second locations. The third slot is configured to mate with a third pin and to align the wafer and the element along a second axis different from the first axis.

In one embodiment, the wafer comprises a material that has a coefficient of thermal expansion that is lower than a coefficient of thermal expansion of a material of the element.

In one embodiment, the first axis and the second axis are substantially perpendicular to each other.

In one embodiment, the first slot includes an oval slot that is configured to receive the first pin, and a major axis of the oval slot of the first slot extends along the first axis. The third alignment slot includes an oval slot that is configured to receive the third pin, and a major axis of the oval slot of the third slot extends along the second axis.

In one embodiment, the wafer further includes a reinforcement feature thereon. The reinforcement feature can include an opening that aligns with the first slot. A size of the opening of the reinforcement feature can be smaller than a size of the first slot such that the reinforcement feature is configured to impede the first pin from physically contacting the wafer.

In one embodiment, the wafer comprises a plurality of integrated circuit dies.

### BRIEF DESCRIPTION OF THE DRAWINGS

Specific implementations will now be described with reference to the following drawings, which are provided by way of example, and not limitation.

FIG. 1A is an exploded view of a processing system.

FIG. 1B is an assembled view of the processing system of FIG. 1A.

FIG. 2A is a schematic perspective view of a system on wafer (SoW) according to an embodiment.

FIG. 2B is an enlarged view of a portion of the SoW illustrated in FIG. 2A.

FIG. 3 is a schematic perspective view of a heat dissipation structure according to an embodiment.

FIG. 4 shows a top plan view of an alignment structure according to an embodiment.

FIG. 5A is a schematic perspective view of a reinforcement feature according to an embodiment.

FIG. 5B is a schematic top plan view of an alignment feature according to an embodiment.

FIG. 5C is a schematic cross-sectional side view of an assembly that includes an alignment structure according to an embodiment.

FIG. 6A is a schematic perspective view of an input/output (I/O) frame according to an embodiment.

FIG. 6B is a schematic perspective view of a cooling system according to an embodiment.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

System on a wafer (SoW) assemblies can include a SoW and a heat dissipation structure that is coupled to the SoW. The SoW can include an array of integrated circuit dies. The integrated circuit dies of the SoW can generate heat during operation. The heat dissipation structure can dissipate heat generated in the SoW. In some applications, it can be significant to align the SoW relative to the heat dissipation structure with a relatively high precision. Locking pins can be used to ensure that the SoW and the heat dissipation structure are aligned to one another. However, locking pins can damage the SoW due to mismatch between a coefficient of thermal expansion (CTE) of the SoW and a CTE of the heat dissipation structure.

Embodiments disclosed herein relate to SoW assemblies that include an alignment structure for aligning stacked SoW assembly structures that can achieve alignment with a relatively high precision while preventing and/or mitigating damage to the elements due to a CTE mismatch. The SoW assembly structures can be referred to as elements. The alignment structure can include alignment slots and pins that are disposed in the alignment slots. Alignment slots of alignment structures disclosed herein consist of 3 slots. Alignment structures disclosed herein can align a first element and a second element stacked with the first element in a processing system. For example, the first element can comprise a SoW and the second element can comprise a heat dissipation structure. As another example, the first element can comprise a cooling system and the second element can comprise an input/output (I/O) frame. Accordingly, a thermal system can include one of the stack elements (e.g., a heat dissipation structure or a cooling system). The first element and the second element are both SoW assembly structures. In some embodiments, an alignment slot can be formed in or with the SoW, and the pin can be positioned on or with the heat dissipation structure that is stacked on the SoW. The alignment structure can include a reinforcement feature that protects the SoW from the pin.

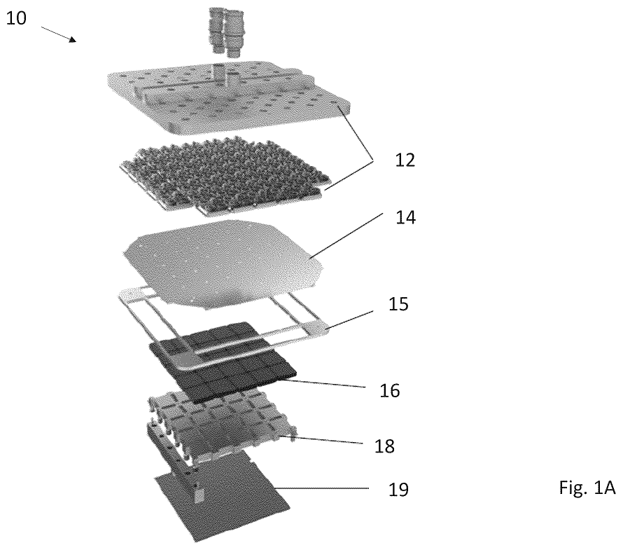

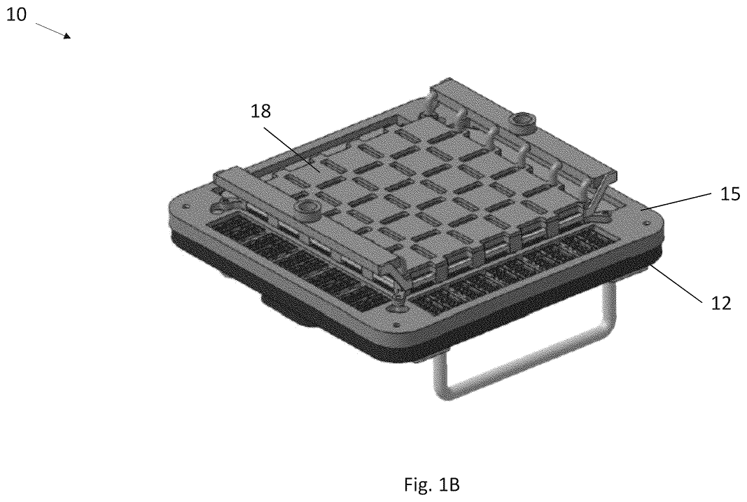

FIGS. 1A and 1B illustrate a processing system 10 in accordance with aspects of this disclosure. FIG. 1A is an exploded view of the processing system 10. FIG. 1B is an assembled view of the processing system 10. Features of this disclosure, such as a wafer alignment structure, can be implemented in the processing system 10 and/or any other suitable processing system. Features of this disclosure can be implemented in any system that includes two or more elements that have different CTEs. The processing system 10 can have a high compute density and dissipation of heat generated by the processing system 10 can significantly affect the performance of the processing system 10. The processing system 10 can execute trillions of operations per second in certain applications. The processing system 10 can be used in and/or specifically configured for high performance computing and/or computation intensive applications, such as neural network training and/or processing, machine learning, artificial intelligence, or the like. The processing system 10 can implement redundancy. In some applications, the processing system 10 can be used for neural network training to generated data for use by an autopilot system of a vehicle (e.g., an automobile), to implement other autonomous vehicle functionality, to implement Advanced Driving Assistance System (ADAS) functionality, or the like.

As illustrated in FIG. 1A, the processing system 10 includes a heat dissipation structure 12, a SoW 14, an input/output (I/O) frame 15, voltage regulating modules (VRMs) 16, a cooling system 18, and a control broad 19. In the processing system 10, a thermal system includes the heat dissipation structure 12 and the cooling system 18. Each of the illustrated elements of the processing system is a SoW assembly structure. FIG. 1B shows the processing system 10 upside down relative to FIG. 1A. The processing system 10 is shown in FIG. 1B without the control board 19. The heat dissipation structure 12 and the SoW 14 can be vertically stacked and horizontally aligned using an alignment structure that can comprise an alignment feature and an alignment pin. The alignment structure will be described in detail with respect to later figures.

The heat dissipation structure 12 can dissipate heat from the SoW 14. The heat dissipation structure 12 can include a heat spreader. Such a heat spreader can include a metal plate. Alternatively or additionally, the heat dissipation structure 12 can include a heat sink. The heat dissipation structure 12 can include any suitable material with desirable heat dissipation properties. A thermal interface material can be included between the heat dissipation structure 12 and the SoW 14 to reduce and/or minimize heat transfer resistance.

The SoW 14 can include an array of integrated circuit (IC) dies. The IC dies can be embedded in a molding material. The SoW 14 can have a high compute density. The IC dies can be semiconductor dies, such as silicon dies. The array of IC dies can include any suitable number of IC dies. For example, the array of IC dies can include 16 IC dies, 25 IC dies, 36 IC dies, or 49 IC dies. The SoW 14 can be an Integrated Fan-Out (InFO) wafer, for example. InFO wafers can include a plurality of routing layers over an array of IC dies. For example, an InFO wafer can include 4, 5, 6, 8, or 10 routing layers in certain applications. The routing layers of the InFO wafer can provide signal connectivity between the ICs dies and/or to external components. The SoW 14 can have a relatively large diameter, such as a diameter in a range from 10 inches to 15 inches. As one example, the SoW 14 can have a 12 inch diameter.

The I/O frame 15 can contribute to the structural integrity of the processing system 10. The I/O frame 15 can provide support to the VRMs 16 and keep the VRMs 16 in place.

The VRMs 16 can be positioned such that each VRM is stacked with an IC die of the SoW 14. In the processing system 10, there is high density packing of the VRMs 16. Accordingly, the VRMs 16 can consume significant power and generate heat. The VRMs 16 are configured to receive a direct current (DC) supply voltage and supply a lower output voltage to a corresponding IC die of the SoW 14.

The cooling system 18 can provide active cooling for the VRMs 16. The cooling system 18 can provide active cooling for the control board 19. The cooling system 18 can include metal with flow paths for heat transfer fluid to flow through. In the assembled processing system 10, the cooling system 18 can be bolted to the heat dissipation structure 12. This can provide structural support for the SoW 14 and/or can reduce the chance of the SoW 14 breaking. Thermal interface material can be included between the cooling system 18 and the control board 19 to reduce and/or minimize heat transfer resistance.

The control board 19 can include electrical components. Electronics of the control board 19 can provide control signals for the VRMs 16. The control board 19 can include electronics to control operation of the SoW 14.

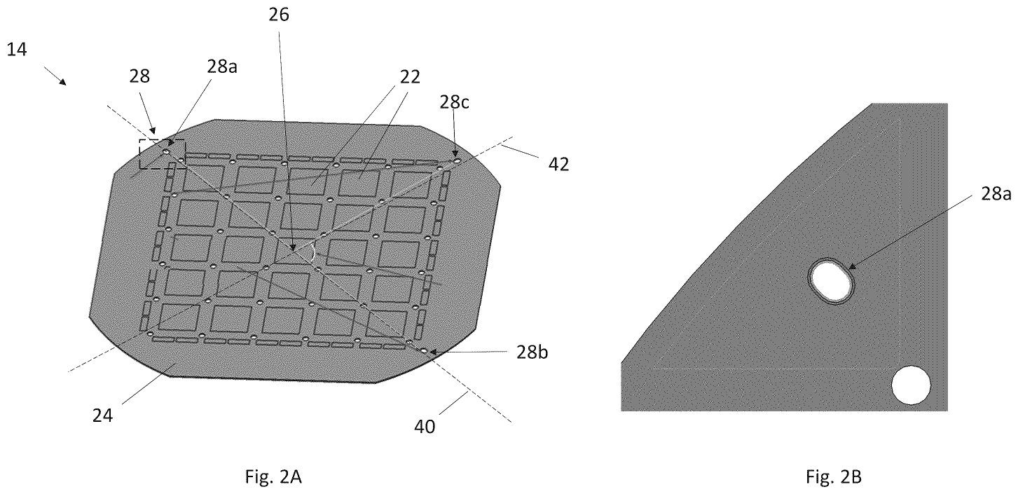

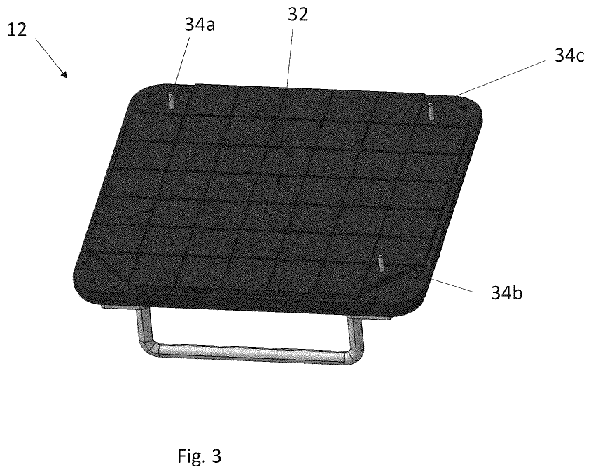

FIG. 2A is a schematic perspective view of a SoW 14 according to an embodiment. FIG. 2B is an enlarged view of a portion of the SoW 14 illustrated in FIG. 2A indicated by dashed rectangle. FIG. 3 is a schematic perspective view of a heat dissipation structure 12. The SoW 14 and the heat dissipation structure 12 can be included in a processing system, such as the processing system 10 illustrated in FIGS. 1A and 1B.

In some embodiments, the heat dissipation structure 12 can comprise a material that has a relatively high coefficient of thermal expansion (CTE). For example, the heat dissipation structure 12 can comprise copper (Cu) and/or aluminum (Al). In some embodiments, the heat dissipation structure 12 can comprise a material that has a CTE in a range from 10 ppm/° C. to 20 ppm/° C. For example, the heat dissipation structure 12 can comprise copper with a CTE of about 17 ppm/° C. In some embodiments, the SoW 14 can comprise a material that has a relatively low coefficient of CTE. For example, the SoW 14 can comprise a silicon (Si) wafer. In some embodiments, the SoW 14 can comprise a material that has a CTE in a range from 1 ppm/° C. to 10 ppm/° C. For example, silicon can have a CTE of about 2.6 ppm/° C. In some embodiments, the CTE of the heat dissipation structure 12 can be two to seven times greater than the CTE of the SoW 14.

The SoW 14 can include an array of integrated circuit (IC) dies 22 positioned on a wafer 24. In some embodiments, the IC dies 22 can include a sensor die, a memory die, an application specific integrated circuit (ASIC) die, and/or a microelectromechanical systems (MEMS) die. In some embodiments, the IC dies 22 can communicate with each other within the SoW 14 through a redistribution layer (RDL) formed therein. The RDL and/or other electrical connections within the SoW 14 can beneficially provide, for example, a relatively low latency in communication between the IC dies 22, a relatively high bandwidth density, and/or a relatively low power distribution network (PDN) impedance. During operation, the SoW 14 generates heat.

In order to obtain desirable heat dissipation, it can be beneficial to align the SoW 14 and the heat dissipation structure 12 with a relatively high precision. For example, it can be beneficial to align the SoW 14 and the heat dissipation structure 12 such that a reference point 26 (e.g., a center point) of the SoW 14 aligns with a reference point 32 (e.g., a center point) of the heat dissipation structure 12. The reference point 26 of the SoW 14 can be aligned with the reference point 32 of heat dissipation structure 12 within a tolerance range of 100 microns to 200 microns. For example, the reference point 26 of the SoW 14 can be aligned with the reference point 32 of heat dissipation structure 12 within a tolerance range of 100 microns to 150 microns, 150 microns to 200 microns, or 125 microns to 175 microns. However, a mechanism for locking the heat dissipation structure 12 and the SoW 14 in place may damage the heat dissipation structure 12 and/or the SoW 14 due to a CTE mismatch.

The heat dissipation structure 12 and the SoW 14 can be vertically stacked. The heat dissipation structure 12 and the SoW 14 can be horizontally aligned using an alignment structure. The alignment structure can comprise slots 28a, 28b, 28c and alignment pins 34a, 34b, 34c. For example, the SoW 14 can comprise the alignment features 28 that can include first to third holes or slots 28a, 28b, 28c as shown in FIGS. 2A and 2B. The slots 28a, 28b, 28c are examples of alignment features of the SoW 14. The heat dissipation structure 12 can have first to third pins 34a, 34b, 34c extending therefrom as shown in FIG. 3. In some embodiments, the heat dissipation structure 12 and the first to third pins 34a, 34b, 34c can be separately formed and assembled together. The slots 28a, 28b, 28c can mate with or receive the first to third pins 34a, 34b, 34c, respectively. The alignment structure can achieve alignment with a relatively high precision while preventing and/or mitigating damaging the elements due to a CTE mismatch between the heat dissipation structure 12 and the SoW 14.

Though the illustrated embodiments show the slots 28a, 28b, 28c in the SoW 14 and the pins 34a, 34b, 34c extending from the heat dissipation structure 12, in some other applications, slots can be formed in the heat dissipation structure 12 and pins can extend from the SoW 14. A support structure (not shown) can be provided around the pins extending from the SoW 14 so that the pins are bonded more strongly and/or reliably to the SoW 14 than without the support structure. Any suitable principles and advantages disclosed herein can be utilized when aligning two or more elements that have different CTEs.

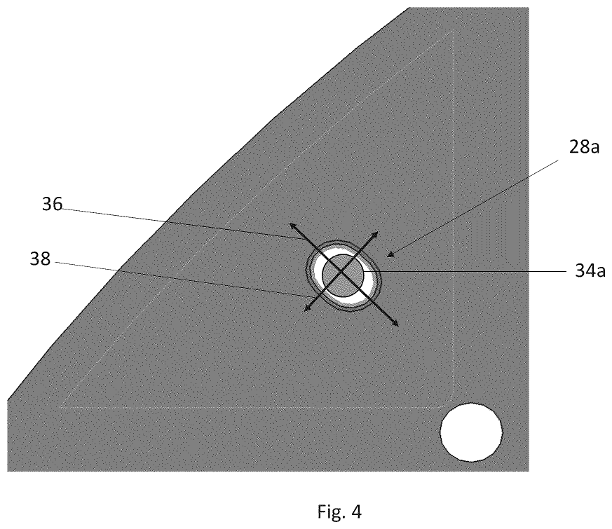

FIG. 4 shows a top plan view of the alignment structure that comprises the first slot 28a and the first pin 34a disposed in the slot 28a. The alignment structure can also include second and third slots 28b and 28c and the second and third pins 34b and 34b disposed in respective second and third slots 28b and 28c in the same or generally similar manner as shown in FIG. 4.

The first slot 28a can allow the first pin 34a to shift or move along a first horizontal axis 40 (see FIG. 2A). The second slot 28b can allow the second pin 34b to shift or move along the first horizontal axis 40 (see FIG. 2A). The third slot 28c can allow the third pin 34c to shift or move along a second horizontal axis 42 (see FIG. 2A). The first horizontal axis 40 and the second horizontal axis 42 are non-parallel to each other. For example, the first horizontal axis 40 and the second horizontal axis 42 can be perpendicular to each other as shown in FIG. 2A. The first horizontal axis 40 and the second horizontal axis 42 can be substantially perpendicular to each other, such as oriented at an angle in a range from 85° to 95° relative to each other. The first horizontal axis 40 and the second horizontal axis 42 are examples of two axes in a plane.

The first to third slots 28a, 28b, 28c can take any suitable shape. In some embodiments, the first to third slots 28a, 28b, 28c can comprise oval or ellipsoid shaped holes. In such embodiments, a major axis 36 of the oval hole of the first slot 28a and a major axis 36 of the oval hole of the second slot 28b can extend along the first horizontal axis 40, and a major axis 36 of the oval hole of the third slot 28c can extend along the second horizontal axis 42. As shown in FIG. 4 the first to third pins 34a, 34b, 34c can be smaller than the first to third slots 28a, 28b, 28c. In some embodiments, the pin 34a, 34b, 34c can comprise a pin having a circular cross section that fits relatively tightly along a minor axis 38 of the oval hole of the slot 28a, 28b, 28c, and have a gap along the major axis 36 of oval hole of the slot 28a, 28b, 28c, thereby allowing the pin 34a, 34b, 34c to move along the major axis 36. Therefore, the pins 34a, 34b, 34c can move to compensate for a CTE mismatch between the heat dissipation structure 12 and the SoW 14, and prevent and/or mitigate damage to the heat dissipation structure 12 and/or the SoW 14. At the same time, the pins 34a, 34b, 34c together with the slots 28a, 28b, 28c can keep the heat dissipation structure 12 and the SoW 14 aligned with each other with a relatively high precision.

With the three slots 28a, 28b, 28c and the respective three pins 34a, 34b, 34c, the heat dissipation structure 12 and the SoW 14 can horizontally align with each other. For example, the first and second slots 28a, 28b and the first and second pins 34a, 34b can contribute to aligning the heat dissipation structure 12 and the SoW 14 along one horizontal axis, and the third slot 28c and the third pin 34c can contribute to aligning the heat dissipation structure 12 and the SoW 14 along another horizontal axis. Therefore, when the pins 34a, 34b, 34c move to compensate for a CTE mismatch between the heat dissipation structure 12 and the SoW 14, alignment between the reference points 26, 32 of the heat dissipation structure 12 and the SoW 14 can be sufficiently maintained.

An alignment structure with three slots 28a, 28b, 28c and the respective pins 34a, 34b, 34c can be more beneficial than including four or more slots and respective pins. For example, an alignment structure with three slots and respective pins allows the heat dissipation structure 12 and the SoW 14 to move relative to one another in both a horizontal orientation and a vertical orientation to maintain alignment. In contrast, an alignment structure with four or more slots can impede the heat dissipation structure 12 and the SoW 14 from moving relative to each other in two orthogonal directions. Therefore, the heat dissipation structure 12 and/or the SoW 14 may be misaligned due to CTE mismatch between the heat dissipation structure 12 and the SoW 14 when there are four or more slots and respective pins. With four slots and corresponding pins, the SoW 14 and the heat dissipation structure 12 can be over constrained such that thermal expansion from CTE mismatches can cause misalignment or damage to the SoW 14 and/or the heat dissipation structure 12.

On the other hand, an alignment structure with two slots and respective pins can allow too much freedom for the heat dissipation structure 12 and the SoW 14 to move relative to each other, which can cause misalignment between the heat dissipation structure 12 and the SoW 14. With two slots and corresponding pins, the SoW 14 and the heat dissipation structure 12 can be under constrained such that thermal expansion from CTE mismatches can cause misalignment or damage to the SoW 14 and/or the heat dissipation structure 12.

A size of the slot 28a, 28b, 28c can be determined based at least in part on a manufacturing tolerance during a stacking process and the CTE mismatch between the heat dissipation structure 12 and the SoW 14. For example, the size of the slot 28a, 28b, 28c can be determined so as to provide sufficient room for the pin 34a, 34b, 34c to move along the major axis 36 without contacting ends of the slot 28a, 28b, 28c.

The first and second slots 28a, 28b have a length along the first horizontal axis 40 and a width along an axis (e.g., the second horizontal axis 42) perpendicular to the first horizontal axis 40. The third slot 28c has a length along the second horizontal axis 42 and a width along an axis (e.g., the first horizontal axis 40) perpendicular to the second horizontal axis 42. In some embodiments, the length of the slot 28a, 28b, 28c can be about 1.5 times the diameter of a pin 34a, 34b, 34c. For example, the length of the slot 28a, 28b, 28c can be about 1.1 to 2, about 1.4 to 2, about 1.1 to 1.7, or about 1.4 to 1.7 times the diameter of a pin 34a, 34b, 34c. In some embodiments, the width of the slot 28a, 28b, 28c can be about the same size of the diameter of a pin 34a, 34b, 34c.

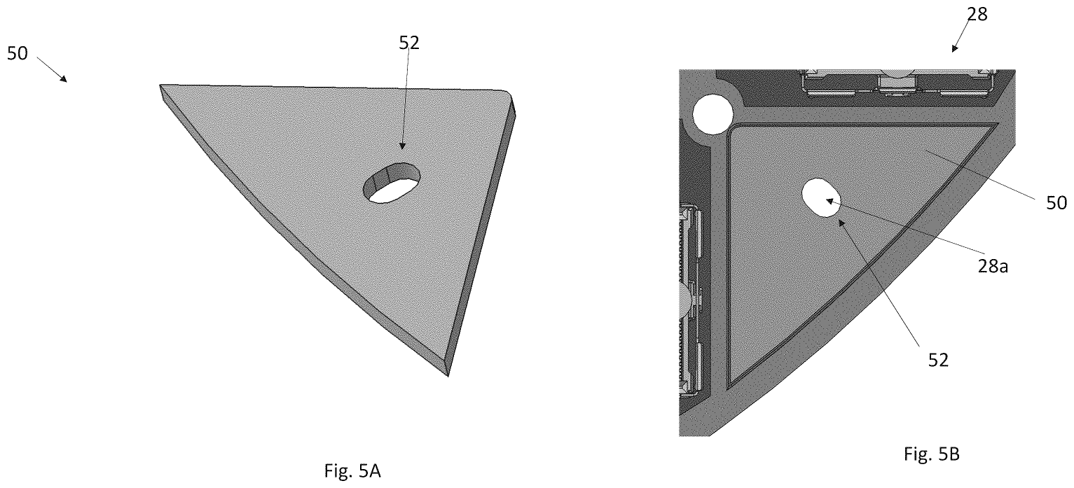

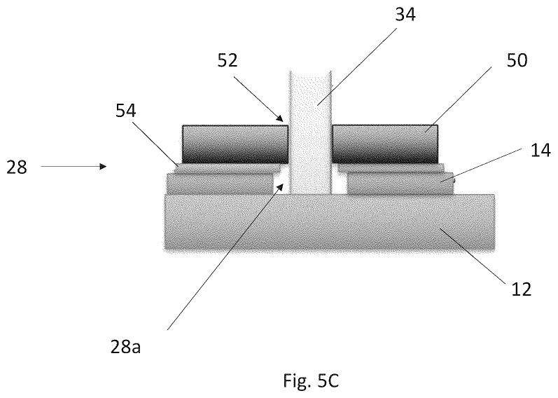

FIG. 5A is a schematic perspective view of a reinforcement feature 50 according to an embodiment. The reinforcement feature 50 can be implemented with any of the alignment structures disclosed herein. FIG. 5B is a schematic top plan view of an alignment feature 28 that includes a slot 28a formed with a SoW 14 and the reinforcement feature 50 disposed on the SoW 14. The two more reinforcement features 50 can be provided to other portions of the SoW 14. For example, the two additional reinforcement features 50 can be positioned above and aligned with slots 28b, 28c (see FIG. 2A). FIG. 5C is a schematic cross-sectional side view of an assembly that includes an alignment structure. As shown in FIG. 5C, the alignment structure includes the alignment feature 28 and a pin 34 that extends from a heat dissipation structure 12.

The reinforcement feature 50 can comprise a material that is more durable and/or stiff than a material of the SoW 14. In some embodiments, the reinforcement feature 50 can comprise a ceramic, a ceramic like material, or an organic material. In some embodiments, the reinforcement feature 50 can comprise a material that has a similar CTE to the CTE of the SoW 14. For example, the CTE of the SoW can be closer to the CTE of the reinforcement feature 50 than the CTE of the heat dissipation structure 12.

The reinforcement feature 50 can comprise an opening 52. A size of the opening 52 can be equal to or smaller than a size of the slot 28a. A shape of the opening 52 can be the same or similar to the shape of the slot 28a. For example, the opening 52 can comprise oval or ellipsoid shaped holes. When the pin 34a moves with in the slot 28a, the reinforcement feature 50 can prevent the pin 34 from contacting the SoW 14, thereby protecting the SoW 14 from being damaged by the pin 34. Accordingly, the reinforcement feature 50 can reduce or eliminate a risk of the SoW 14 chipping and cracking from pin and slot contact forces.

In some embodiments, the reinforcement feature 50 can be coupled with the SoW 14 by way of an adhesive 54. The reinforcement feature 50 can be an alignment board. In some embodiments, the reinforcement feature 50 can be coupled with the SoW 14 by way of a ball grid array (BGA). Such a BGA can align with pads on the SoW 14. The reinforcement feature 50 can be optically aligned with the SoW. After this optical alignment, underfill can then be provided for strength and reliability. The adhesive 54 can comprise an underfill.

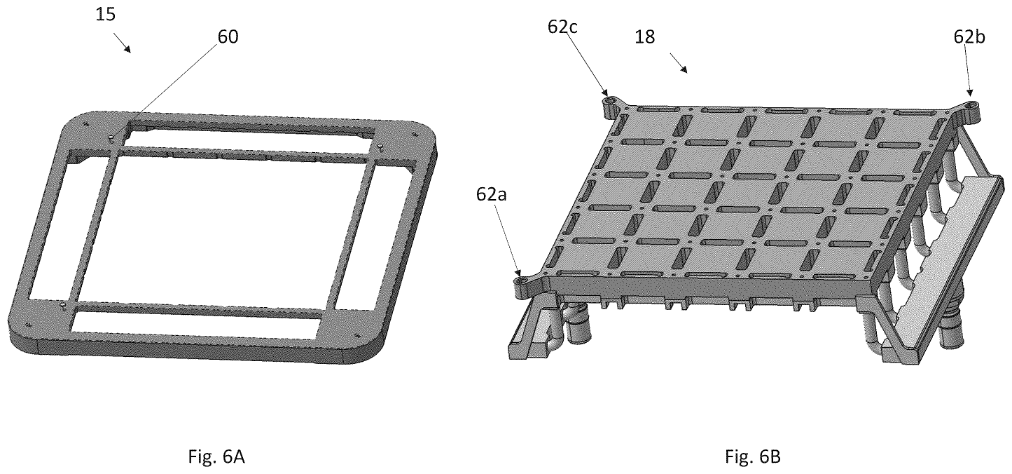

Although embodiments disclosed herein may be related to an alignment structure for aligning a SoW and a heat dissipation structure, any suitable principles and advantages disclosed herein can be applied to an alignment structure anywhere in a processing system, such as between the I/O frame 15 and the cooling system 18 (See FIGS. 1A, 1B, 6A, and 6B). Any suitable principles and advantages disclosed herein related to alignment structures can be applied to maintain precise alignment between two different elements with different respective CTEs in a SoW assembly.

FIG. 6A is a schematic perspective view of an I/O frame 15 according to an embodiment. FIG. 6B is a schematic perspective view of a cooling system 18 according to an embodiment. The I/O frame 15 can receive pins 60 though openings therethrough. The cooling system 18 can comprise slots 62a, 62b, 62c. The slots 62a, 62b 62c can be configured to mate with or receive the pins 60 to align the I/O frame 15 and the cooling system 18. Any suitable principles and advantages disclosed herein can be applied to the pins 60 and the slots 62a, 62b, 62c. In some other embodiments, the I/O frame 15 can comprise slots and the cooling system can comprise pins.

The alignment structures disclosed herein can be used to align two or more SoW assembly structures in a processing system (e.g., the processing system 10 illustrated in FIG. 1A). The alignment structures disclosed herein can be used to align first and second SoW assembly structures in the processing system that have different CTEs. For example, the first SoW assembly structure can be a SoW 14, and the second SoW assembly structure can be a heat dissipation structure 12. As another example, the first SoW assembly structure can be a cooling system 18, and the second SoW assembly structure can be an I/O frame 15.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

The foregoing description has been described with reference to specific embodiments. However, the illustrative discussions above are not intended to be exhaustive or to limit the inventions to the precise forms described. Many modifications and variations are possible in view of the above teachings. Others skilled in the art are thereby enabled to best utilize the techniques and various embodiments with various modifications as suited to various uses.

Although the disclosure and examples have been described with reference to the accompanying drawings, various changes and modifications will become apparent to those skilled in the art. Such changes and modifications are to be understood as being included within the scope of the disclosure.

What is claimed is:

1. A system on a wafer (SoW) assembly comprising:
a first SoW assembly structure including a first slot at a first location, a second slot at a second location, and a third slot at a third location; and
a second SoW assembly structure stacked with the first SoW assembly structure, the second SoW assembly structure having a first pin extending therefrom and at least partially disposed in the first slot, a second pin extending therefrom and at least partially disposed in the second slot, and a third pin extending therefrom and at least partially disposed in the third slot,
wherein the first slot and the second slot are shaped so as to allow the first pin and the second pin to move along a first axis in a plane, and the third slot is shaped so as to allow the third pin to move along a second axis in the plane that is different from the first axis, and
wherein either the first SoW assembly structure or the second SoW assembly structure is included in a thermal system that is configured to cool a SoW.

2. The SoW assembly of claim 1, wherein the first SoW assembly structure comprises the SoW and the second SoW assembly structure comprises a heat dissipation structure.

3. The SoW assembly of claim 2, further comprising a reinforcement feature coupled to the SoW, wherein the reinforcement feature comprises an opening that aligns with the first slot, wherein a size of the opening is smaller than a size of the first slot such that the reinforcement feature impedes the first pin from physically contacting the SoW.

4. The SoW assembly of claim 3, wherein the opening has an oval shape.

5. The SoW assembly of claim 1, wherein the first axis is substantially perpendicular to the second axis.

6. The SoW assembly of claim 1, wherein the first SoW assembly structure comprises a cooling system and the second SoW assembly structure comprises an input/output frame, and the first and second SoW assembly structures are stacked with the SoW.

7. A system on a wafer (SoW) assembly comprising:
a first SoW assembly structure having a first coefficient of thermal expansion, the first SoW assembly structure including a first slot at a first location, a second slot at a second location, and a third slot at a third location; and
a second SoW assembly structure stacked on the first SoW assembly structure, the second SoW assembly structure having a second coefficient of thermal expansion that is different than the first coefficient of thermal expansion, the second SoW assembly structure having a first pin extending therefrom and at least partially disposed in the first slot, a second pin extending therefrom and at least partially disposed in the second slot, and a third pin extending therefrom and at least partially disposed in the third slot,
wherein the first slot and the second slot are shaped so as to allow the first pin and the second pin to move along a first axis in a plane, and the third slot is shaped so as to allow the third pin to move along a second axis in the plane, the second axis being different from the first axis.

8. The SoW assembly of claim 7, wherein the first SoW assembly structure is stacked with a SoW.

9. The SoW assembly of claim 7, wherein the second coefficient of thermal expansion is greater than the first coefficient of thermal expansion.

10. The SoW assembly of claim 7, wherein the first SoW assembly structure comprises a SoW.

11. The SoW assembly of claim 10, further comprising a reinforcement feature coupled with the SoW.

12. The SoW assembly of claim 11, wherein the reinforcement feature comprises an opening that aligns with the first slot, and a size of the opening is smaller than a size of the first slot.

13. The SoW assembly of claim 7, wherein the first axis and the second axis are substantially perpendicular to each other.

14. The SoW assembly of claim 7, wherein the first slot comprises an oval slot configured to receive the first pin, and wherein a major axis of the oval slot of the first slot extends along the first axis.

15. The SoW assembly of claim 14, wherein the third slot comprises an oval slot configured to receive the third pin, and a major axis of the oval slot of the third slot extends along the second axis.

16. The SoW assembly of claim 7, wherein the second SoW assembly structure comprises a heat dissipation structure.

17. The SoW assembly of claim 7, wherein the first SoW assembly structure includes no more than three slots that are configured to receive pins that extend from the second SoW assembly structure.

18. A wafer with an alignment structure for aligning the wafer with an element stacked vertically on the wafer, the wafer comprising:
a first slot formed at a first location of the wafer, the first slot configured to mate with a first pin and to align the wafer and the element along a first axis, the first slot shaped to allow the wafer to move along the first axis when the first slot and the first pin are mated;
a second slot formed at a second location of the wafer different from the first location, the second slot configured to mate with a second pin and to align the wafer and the element along the first axis; and
a third slot formed at a third location of the wafer different from the first and second locations, the third slot configured to mate with a third pin and to align the wafer and the element along a second axis different from the first axis.

19. The wafer of claim 18, wherein the wafer comprises a material that has a coefficient of thermal expansion that is lower than a coefficient of thermal expansion of a material of the element.

20. The wafer of claim 18, wherein the first axis and the second axis are substantially perpendicular to each other.

21. The wafer of claim 18, wherein the first slot comprises an oval slot configured to receive the first pin, a major axis of the oval slot of the first slot extends along the first axis, the third slot comprises an oval slot configured to receive the third pin, and a major axis of the oval slot of the third slot extends along the second axis.

22. The wafer of claim 18, further comprising a reinforcement feature thereon, the reinforcement feature comprising an opening that aligns with the first slot, a size of the opening of the reinforcement feature being smaller than a size of the first slot such that the reinforcement feature is configured to impede the first pin from physically contacting the wafer.

23. The wafer of claim 18, wherein the wafer comprises a plurality of integrated circuit dies.
